(19) United States
(12) Patent Application Publication
(10) Pub. No.: US 2006/0082391 A1
(43) Pub. Date: Apr. 20, 2006

(54) Set-reset (S-R) latch based deglitch circuit

(76) Inventors: David Hsu, Cupertino, CA (US); Robert W. Hulvey, Redondo Beach, CA (US)

Correspondence Address: CHRISTIE, PARKER & HALE, LLP, PO BOX 7068, PASADENA, CA, 91109-7068, US

(21) Appl. No.: 11/252,868

(22) Filed: Oct. 17, 2005

Related U.S. Application Data
(60) Provisional application No. 60/619,167, filed on Oct. 15, 2004.

(51) Int. Cl. G01R 29/02

(52) U.S. Cl. 327/34

(57) ABSTRACT

Methods and systems that use a simple hardware circuit and/or digital logic solution to identify and remove both positive and negative glitches from a signal. For this hardware circuit and/or digital logic solution, a glitch is referred to as an unwanted pulse with a width less than a specified duration, and is generally caused by noise or improper operation by other devices. A positive glitch occurs when the input signal has been logic low for some time, while a negative glitch occurs when the input signal has been logic high for some time. In one embodiment, the hardware circuit and/or digital logic solution removes noises from signals transmitted between a digital circuit and its switches and/or remote sensors, such as switches of keyboards and mice.

### CROSS-REFERENCE TO RELATED APPLICATION(S)

This application claims the benefit of U.S. Provisional Application No. 60/619,167, filed Oct. 15, 2004, the entire content of which is incorporated herein by reference.

### FIELD OF THE INVENTION

The present invention generally relates to a digital circuit that receives digital input signals from a mechanical switch (e.g., of a keyboard, a mouse, and/or etc.) and/or a remote sensor. More generally, the invention relates to a deglitch circuit that reduces noise on digital output signals from one digital circuit before they are applied as input to another digital circuit.

### BACKGROUND OF THE INVENTION

Digital input signals may be produced from a user activated mechanical switch or other type of input mechanism which translates user activity into an electrical signal. It may also be from a sensor such as a light detector, motion detector, etc. or come from another digital circuit or integrated circuit (IC). The digital inputs may feed into another digital circuit and serve, for example, as an interrupt input signal for a microprocessor or to logic which would wake-up a processor from a low-power “sleep” mode.

An input signal may contain noises or glitches (e.g., undesired signal transitions) that may be induced by electromagnetic fields which in turn may be due to electrostatic discharge (ESD), other nearby signals (crosstalk), lightening, other electromagnetic devices, motors, etc. By way of an example, a typical computer keyboard contains a matrix of switches. The matrix is typically connected together by many long conductive traces in a printed circuit, often printed on a flexible sheet of plastic. This matrix can act like a large array of antennas, and hence may pick up noise or glitches from nearby sources. In another example, a remotely located sensor generates the input signal, and the input signal must then travel on a wire over a long distance to a circuit which then processes the input signal. The longer the wire over which the input signal has to travel, the more susceptible the signal is to the above described environmental noise sources.

Glitches may also be caused by mechanical “bounces” which occur in mechanical switches. When the switch is closed or opened by the user, the conductive contacts within the switch may literally bounce on or scrape against one another before settling into a state where the contacts are reliably closed or opened.

Glitches further may be generated by poorly designed digital circuitry. Timing variances in digital circuitry, especially in circuits known as digital state machines, can produce unintended glitches on output signals.

Glitches may be handled (e.g., removed) by employing algorithms in firmware which take multiple samples of the input signal, and then analyze a set of samples to recognize and then filter out the noise and/or glitches. A drawback of using firmware to filter out glitches is that the firmware must be running when the noise and/or glitches occur in order to process them. Since multiple samples are needed, the firmware must run faster in order to process the data gathered. Accordingly, there is a need to provide a straight forward hardware solution that can distinguish undesired noise or glitches from the desired data signal that needs to be provided to its intended destination. It addition, there is a need for a hardware deglitcher or a deglitch circuit that can remove a noise from a signal before firmware receives the signal so that the firmware is then able to run slower.

In addition, in battery-powered systems, large portions of the system may be shut down when there is no significant input detected. A noise on input signals may be incorrectly interpreted as an intended input causing the logic to be powered up so that the input signal has to be processed further (e.g., by firmware) to determine if it is a noise or a valid input signal. Accordingly, there is a need for a deglitcher that can reduce or even eliminate these “false alarms” so that the system can remain in a low-power state more often, which in turn lengthens the battery life of the system.

### SUMMARY OF THE INVENTION

The invention relates to methods and associated systems for removing both positive and negative glitches from a signal. A glitch can be defined as an unwanted pulse with a width less than a specified duration. A positive glitch occurs when an input signal (e.g., from a signal producing node) has been low for some time, while a negative glitch occurs when the input signal has been high for some time. Embodiments of the present invention provide straightforward hardware digital logic solutions to identify and remove these two types of glitches.

In an embodiment of the present invention, a deglitch circuit coupled between a signal producing node and a signal processing node is provided. The deglitch circuit includes a delay block, a first logic gate, a second logic gate, and an SR latch. The delay block is coupled to receive a data signal from the signal producing node and to produce a delay data signal. The first logic gate has a first gate input, a second gate input, and a first gate output. The first gate input is coupled to receive the data signal from the signal producing node and the second gate input is coupled to receive the delay data signal from the delay block. The second logic gate has a third gate input, a fourth gate input, and a second gate output. The third gate input is coupled to receive the data signal from the signal producing node and the fourth gate input is coupled to receive the delay data signal from the delay block. The SR latch has a first latch input, a second latch input, and a latch output. The first latch input is coupled to the first gate output and the second latch input is coupled to the second gate output. The SR latch provides a deglitched data signal based on the data signal via the latch output to the signal processing node for processing.

In addition, in one embodiment, the first logic gate is used to remove a positive glitch from the data signal and the second logic gate is used to remove a negative glitch from the data signal. The first logic gate may include an and-gate and the second logic gate may include a nor-gate.

In another embodiment of the invention, a method of deglitching a data signal using a digital logic circuit is provided. The method includes receiving a data signal from a signal producing node. The received data signal is then delayed for a predetermined period to produce a delay data signal. The data signal is then provided to a first gate input of a first logic gate and a first gate input of a second logic gate in a substantially parallel manner. In addition, the delay data signal is provided to a second gate input of the first logic gate and a second gate input of the second logic gate in a substantially parallel manner. An SR latch coupled to an output of the first logic gate and an output of the second logic gate then provides a deglitched data signal based on the data signal from the SR latch to a signal processing node.

In addition, the method may further include deciding a size of a glitch that is to be removed from the data signal, setting the delay block to the decided size, and/or making sure that the delay is large enough so that SR latch timing constraints are met.

A more complete understanding of the use of set-reset (S-R) latch based deglitch circuit will be afforded to those skilled in the art, as well as a realization of additional advantages and objects thereof, by a consideration of the following detailed description. Reference will be made to the appended sheets of drawings which will first be described briefly.

### BRIEF DESCRIPTION OF THE DRAWINGS

These and other features, aspects and advantages of the present invention will be more fully understood when considered with respect to the following detailed description, appended claims and accompanying drawings, wherein:

FIG. 1 is a schematic diagram of a communication architecture to which embodiments of the present invention can be applied;

FIG. 2 is a schematic diagram of another communication architecture pursuant to aspects of the present invention;

FIG. 3 is a more detailed schematic diagram of a deglitch circuit according to an embodiment of the present invention;

FIG. 4 is a timing diagram of various waveforms applied to and/or produced by various components of the deglitch circuit of FIG. 3 in accordance with a first exemplary operation of the present invention;

FIG. 5 is a timing diagram of various waveforms applied to and/or produced by various components of the deglitch circuit of FIG. 3 in accordance with a second exemplary operation of the present invention;

FIG. 6 is a timing diagram of various waveforms applied to and/or produced by various components of the deglitch circuit of FIG. 3 in accordance with a third exemplary operation of the present invention; and

FIG. 7 is a timing diagram of various waveforms applied to and/or produced by various components of the deglitch circuit of FIG. 3 in accordance with a fourth exemplary operation of the present invention.

### DETAILED DESCRIPTION OF THE INVENTION

The invention is described below, with reference to detailed illustrative embodiments. It will be apparent that the invention can be embodied in a wide variety of forms, some of which may be quite different from those of the disclosed embodiments. Consequently, the specific structural and functional details disclosed herein are merely representative and do not limit the scope of the invention.

The present invention is directed to systems and methods that remove both positive and negative glitches from a signal. In the context of the following discussion, a glitch is referred to as an unwanted signal pulse with a width less than a specified duration. A positive glitch occurs when an input signal (e.g., from a signal producing node) has been logic low for some time, while a negative glitch occurs when the input signal has been logic high for some time. The present invention provides a low level hardware solution for removing both positive and negative glitches from a signal.

In one embodiment of the present invention, a hardwired circuit is provided to remove both positive and negative glitches. The circuit is simple and is made up of basic logic components. As envisioned, embodiments of the present invention may be realized by circuits using simple hardware design language (HDL) coding (e.g., Verilog). Further, certain embodiments may be realized by circuits designed for a particular application, such as application specific integrated circuits (ASIC) (as opposed to general integrated circuits, such as microprocessors or random access memories in PCs). In particular, an embodiment of the present invention can be implemented in a simple customized ASIC chip created to detect and remove both positive and negative glitches from a signal that would otherwise be handled by high level firmware.

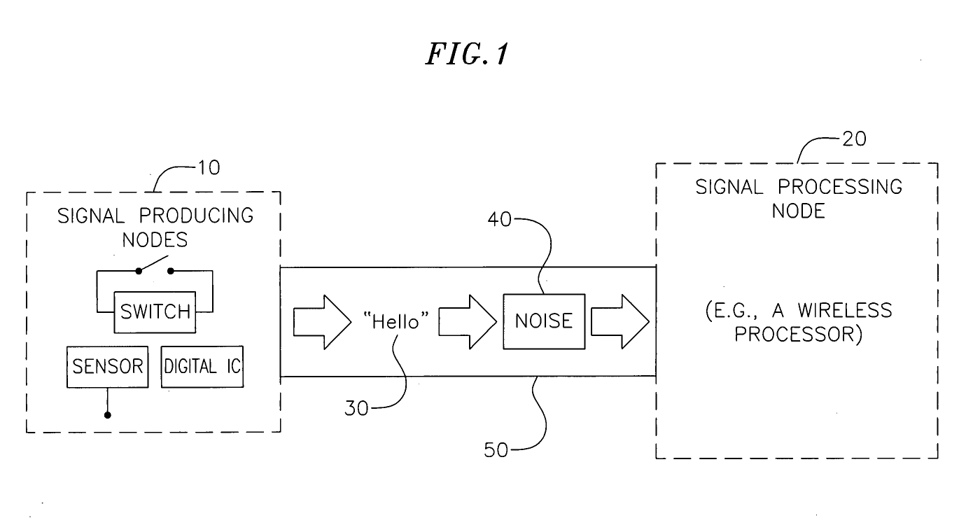

Referring now to FIG. 1, there is shown one or more signal producing nodes 10 (such as remote sensors and/or switches of keyboards, mice, trackballs, touchpads, gamepads, joysticks, remote controllers, etc.) that communicate a “Hello” signal 30 to a signal processing node 20 to process the “Hello” signal 30 via a conductive and/or connection medium 50 (e.g., conductive traces in a printed circuit or a conductive wire). The “Hello” signal 30 may then be transmitted from the signal processing node 20 to a central processor and/or central processing unit (not shown) using hardwires, infrared lights and/or radio frequencies.

In particular, the signal producing nodes 10 may provide (and/or transmit) the “Hello” signal 30 via the conductive and/or connection medium 50 (e.g., the plurality of conductive traces and/or the conductive wire) to the signal processing node 20. The signal processing node 20 may then transmit the “Hello” signal 30 wirelessly to the central processor and/or the central processing unit (CPU) using a frequency hopping spread-spectrum (FHSS) radio technique. In the FHSS technique, the signal processing node 20 includes a wireless processor that uses a plurality of individual, pseudo-randomly chosen radio frequencies within a designated range, changing from one to another on a regular basis. In addition, when the signal processing node 20 (e.g., via its wireless processor) comes within range for transmitting the “Hello” signal 30 to the central processor and/or the CPU, a personal-area network or PAN (not shown) may be automatically established by the signal processing node 20 with the central processor and/or the CPU (e.g., via another wireless processor of the central processor) to communicate the “Hello” signal 30. Once the PAN is established, the signal processing node 20 and the central processor and/or the CPU may then pseudo-randomly hop frequencies in unison to communicate the “Hello” signal 30 from the signal processing node 20 to the central processor and/or the CPU and to avoid other PANs that may be operating in the same area. Other multi-access wireless communication formats and/or techniques may also be used to communicate the “Hello” signal from the signal producing nodes 10 to the signal processing node 20 and then to the central processor and/or the CPU. As such, the invention is not, thereby, limited.

FIG. 1 also shows that a noise (or glitch) 40 is provided to the signal processing node 20. As already described above and in more detail below, the noise 40 can disrupt or change how the “Hello” signal 30 is processed by the signal processing node 20. In particular, as is shown in FIG. 1, the noise 40 may be processed with the “Hello” signal 30 by the signal processing node 20 instead of only the intended “Hello” signal 30.

As envisioned, a deglitch circuit in one embodiment of the present invention is used to remove certain types of noise signals from digital inputs to another digital circuit. As such, it is inserted between a signal producing node (e.g., a signal source) and a signal processing node (e.g., a digital circuit) that receives the input signal.

The input signal deglitched by the deglitch circuit (or deglitcher) may be from a user activated mechanical switch or other type of input mechanism which translates user activity into an electrical signal. It may also be from a sensor such as a light detector, motion detector, etc. It may also come from another digital circuit or IC.

The output signal from the deglitcher generally feeds another digital circuit. The signal may, for example, serve as an interrupt signal for a microprocessor and/or to logic which would wake-up a processor (e.g., a central process and/or a central processing unit) from a low-power “sleep” mode.

The input signal may contain noise or glitches (e.g., undesired signal transitions), which may be induced by electromagnetic fields which in turn may be due to electrostatic discharge (ESD), other nearby signals (crosstalk), lightening, other electromagnetic devices, motors, etc.

In particular, if the input signal which needs to be deglitched travels over a long wire, it will be more susceptible to such environmental noise sources.

In addition, poor electrical connections may also lead to such a noise. Further, timing variances in and/or poor design of certain digital circuits may also result in glitches.

By way of an example, a typical computer keyboard contains a matrix of switches. The matrix is typically connected together by many long conductive traces in a printed circuit, often printed on a flexible sheet of plastic. This matrix can act like a large array of antennas, and hence may pick up noise from nearby sources. Battery-operated devices such as wireless keyboards are especially susceptible to such noise, as the electrical ground in such devices is referenced only to the batteries in the unit, and hence the nodes of the matrix are said to be “floating” relative to other nearby electrical devices which can serve as noise sources. In some applications, a remotely located sensor generates the input signal, and the input signal must then travel on a wire over a long distance to a circuit which then processes the input signal. The distance over which the signal travels (here again) can makes it more susceptible to noise sources along the way.

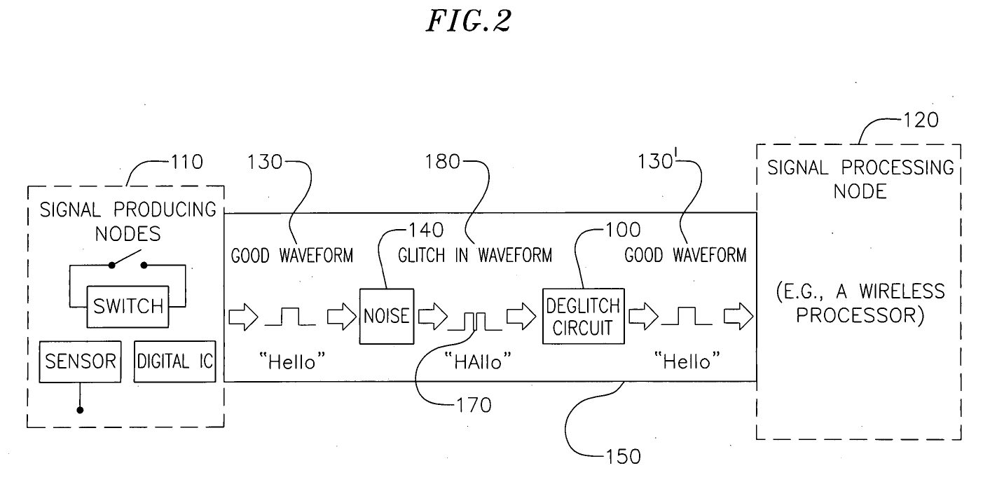

Referring now to FIG. 2, there is shown one illustrative embodiment of a deglitch circuit 100 of the present invention used with one or more signal producing nodes 110 and a signal processing node 120. The signal producing nodes 110 and the signal processing node 120 are coupled via a conductive and/or connector medium 150. The deglitch circuit 100 may be in the form of an application-specific integrated circuits (ASIC) chip that is designed to collect data signals from the signal producing nodes 110. For example, the deglitch circuit 100 may interact with the one or more signal producing nodes 110, where a signal producing node of the signal producing nodes 110 receives a particular mechanical input from a human user and generates corresponding digital input signal, such as a “Hello” signal or waveform 130 shown in FIG. 2. Moreover, while only two signal producing nodes (e.g., a switch and a remote sensor) are shown in FIG. 2, it should be apparent that a signal producing node can take many forms and the number of signal producing nodes can be one, two, or any greater number.

In FIG. 2, a noise (or glitch) 140 is also shown with the “Hello” signal waveform 130 to form a glitch 170 in the waveform 180. In particular, FIG. 2 shows that the “HAllo” signal waveform 180 having the glitch 170 is formed due to combination of the noise 140 with the “Hello” signal waveform 130. The “HAllo” signal waveform 180 then enters the deglitch circuit 100 that identifies and removes the glitch 170 from the waveform 180 to reform a deglitched waveform 130′. This deglitched waveform 130′ is then passed to the signal processing node 120 from the deglitch circuit 100 and the intended “Hello” is processed by the signal processing node 120. It should be understood by those skilled in the art that the deglitch circuit 100 is not limited to a position located outside the signal processing node 120, and that a whole or a part of the deglitch circuit 100 can be located inside the signal processing node 120 and/or any other place to provide an intended deglitch function for the signal processing node 120. Moreover, it should be apparent to those skilled in the art that the noise 140 and/or the glitch 170 can be received by the signal processing node 120 and/or the deglitch circuit 100 at separate, independent, and/or different time and/or space frames. As such, the present invention is not limited to a case where the noise 140 and/or the glitch 170 are combined prior to being deglitched by the deglitch circuit 100 and/or processed by the signal processing node 120.

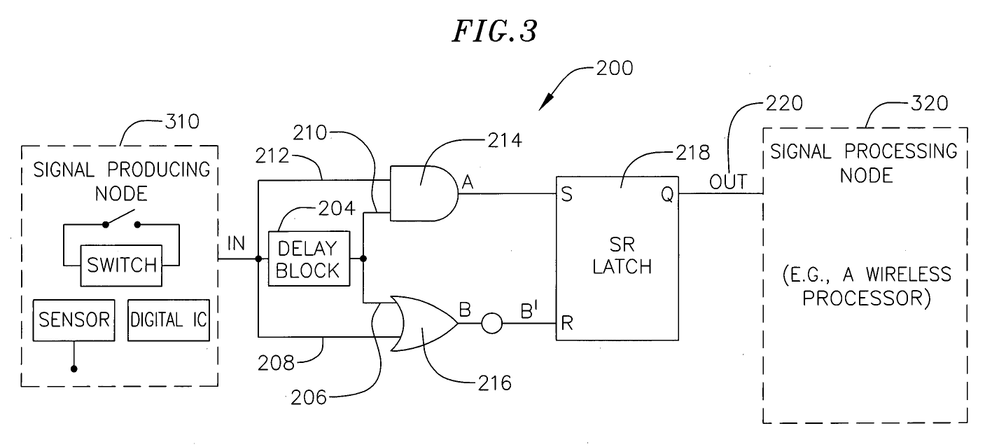

Referring now to FIG. 3, a glitch circuit 200 in one embodiment of the present invention includes an and-gate 214 that removes positive glitches, a nor-gate that removes negative glitches 216, and an SR latch 218 that processes the outputs A, B′ from the and-gate and nor-gate filters 214, 216. In addition, a delay block 204 is coupled to a first gate input 210 of the and-gate 214 and a first gate input 208 of the nor-gate 216.

In particular, FIG. 3 shows that a signal producing node 310 is coupled to a second gate input 212 of the and-gate 214, a second gate input 206 of the nor-gate 216, and the delay block 204 in a substantial parallel manner. Further, the delay block 204 is coupled to the first gate input 210 of the and-gate 214 and the first gate input 208 of the nor-gate 216 in a substantially parallel manner.

The and-gate 214 performs a logical “and” operation on its two gate inputs 212, 210. That is, if a first value provided to the gate input 212 and a second value provided to gate input 210 are both 1, then an output value on the output A of the and-gate 214 should be 1. If the values on the gate input 212 and the gate input 210 are both 0, then the output value should be 0. If the value on the gate input 212 is 0 and the value on the gate input 210 is 1, then the output value should be 0. If the value on the gate input 212 is 1 and the value on the gate input 210 is 0, then the output value should also be 0.

By contrast, the nor-gate 216 performs a logical “or” and “not” operation on its two gate inputs 208, 206. That is, if values on the gate input 208 and the gate input 206 are both 1, then an output value on the output B′ of the nor-gate 216 should be 0. If the values on the gate input 208 and the gate input 206 are both 0, then the output value should be 1. If the value on the gate input 208 is 0 and the value on the gate input 206 is 1, then the output value should be 0. If the value on the gate input 208 is 1 and the value on the gate input 206 is 0, then the output value of the nor-gate 216 should again be 0.

The output A of the and-gate 214 is coupled to a first input S of the SR latch 218 and the output B′ of the nor-gate 216 is coupled to a second input R of the SR latch 218. The SR latch 218 includes a mechanism (not shown) that processes the values applied to the inputs S and R to produce an output signal 224 (or Out) on a output Q of the SR latch 218. This output signal 224 (Out) is then passed on to a signal processing node 320 for processing. The SR latch 218 produces an unusual output signal 224 as compared to the output values provided by the and-gate 214 and the nor-gate 216. For example, if a value provided on the first input S and a value provided on the second input R are opposites of one another, then a value of the output signal 224 (Out) follows the value of the first input S. If the values on both the first input S and the second input R are switched to 0, then the output signal 224 (Out) of the latch is the same as the value initially on the output Q prior to the switching.

As an analogy, an SR latch of the present invention can be thought of as a lamp with two pull-chains hanging from it. The lamp can be on or off. One pull-chain turns the lamp on and the other turns the lamp off. If the “on” chain is pulled, the light goes on and if the “off” chain is pulled the light goes off. If neither the “on” chain or the “off” chain is pulled, then if the lamp was on, it remains on; if the lamp was off, it remains off. Hence, the SR-latch is said to “remember” its state, and such a circuit element is referred to in the art as a memory element.

In general and as envisioned in an operational embodiment of the present invention, a delay value for a delay block (e.g., the block 204 of FIG. 3) can be selectively set to a maximum width of a glitch that is to be filtered by a deglitch circuit (e.g., the deglitch circuit 200). For example, if the delay block is programmed with a delay of five (5) ns, then glitches of width 5 ns and lower will not pass through the glitch circuit. In the context of the present invention, the width of the glitch is assumed to be substantially shorter (or smaller) than normal signal high/low duration (or width).

In particular, an operational embodiment of the present invention includes: (1) deciding a size of a glitch that is to be removed; (2) setting the delay block to the decided size; and/or (3) making sure that the delay is large enough so that SR latch timing constraints are met. For example, the two inputs (S and R) of an SR latch (e.g., the SR latch 218) should not both change at once and/or to one. Further, the delay should be large enough to ensure that only after one input has totally propagated throughout the SR latch does the other input change.

Referring now to FIG. 4, in a first exemplary operation of the present invention, a waveform of a positive input signal (in) is applied to the deglitch circuit 200 of FIG. 3. Referring also to FIG. 3, the waveform of the positive input signal (in) is applied to the first gate input 210 of the and-gate 214, the first gate input 208 of the nor-gate 216, and the delay block 204 in a substantial parallel manner. The delay block 204 then produces a delay input waveform (in_delay) that is applied to the second gate input 212 of the and-gate 214 and the second gate input 208 of the nor-gate 216 in a substantially parallel manner. As can be seen by the logical timing flow on the various components of the deglitch circuit 200 (e.g., the delay block 204 producing the in_delay waveform, the and-gate 214 producing the A waveform, the nor-gate producing the B′ waveform, and the SR latch 218 producing the Out waveform), the waveform of the positive input signal (in) is not affected by the deglitch circuit 200 with the exception of a delay in its timing. That is, the waveform of the output signal (Out) of the SR latch 218 is substantially similar to the waveform of the delay input (in_delay) of the delay block 204.

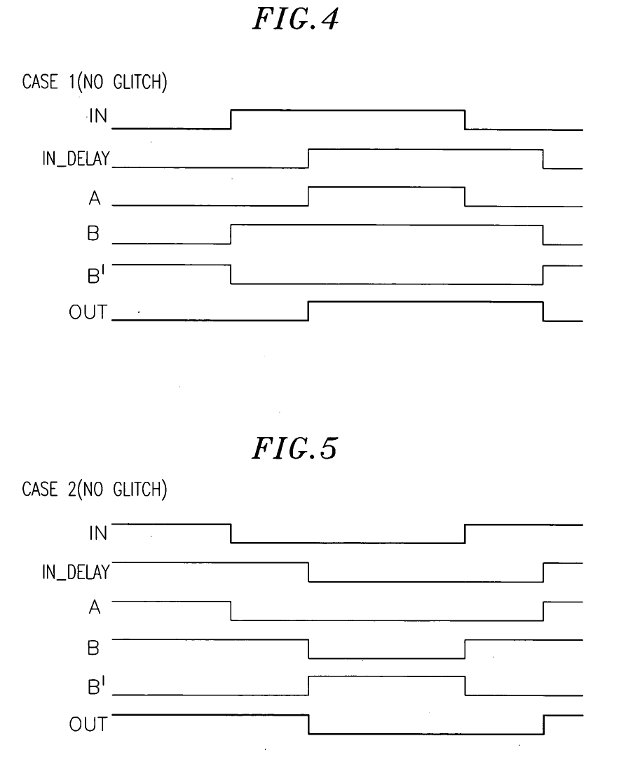

In a second exemplary operation and referring now to FIG. 5, a waveform of a negative input signal (in) is applied to the deglitch circuit 200 of FIG. 3. Similar to the positive input signal waveform of FIG. 4, as can be seen by the logical timing flow of FIG. 5, the waveform of the negative input signal (in) is also not affected by the deglitch circuit 200 with the exception of a delay in its timing. That is, the waveform of the output signal (Out) of the SR latch 218 is substantially similar to the waveform of the delay input (in_delay) of the delay block 204.

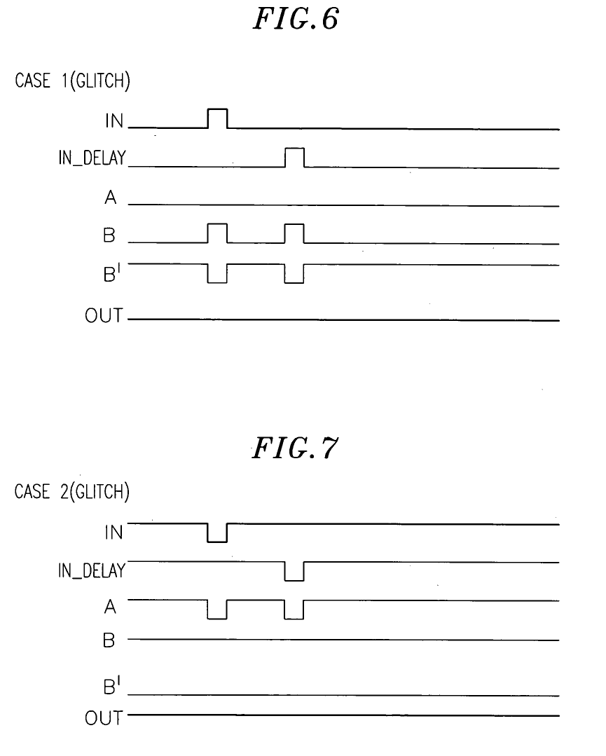

By contrast and referring now to FIG. 6, a waveform of a positive glitch (in) is applied to the deglitch circuit 200 of FIG. 3 in a third exemplary operation of the present invention. As can be seen by the logical timing flow of FIG. 6, the various components of the deglitch circuit 200 (e.g., the delay block 204 producing the in_delay waveform, the and-gate 214 producing the A waveform, the nor-gate producing the B′ waveform, and the SR latch 218 producing the Out waveform) identify the waveform of the positive glitch (in) and eliminate it from the waveform of the output signal (Out) of the SR latch 218.

Referring now to FIG. 7, a waveform of a negative glitch (in) is applied to the deglitch circuit 200 of FIG. 3 in a fourth exemplary operation of the present invention. As can be seen by the logical timing flow of FIG. 7, the various components of the deglitch circuit 200 (e.g., the delay block 204 producing the in_delay waveform, the and-gate 214 producing the A waveform, the nor-gate 216 producing the B′ waveform, and the SR latch 218 producing the Out waveform) also identify the waveform of this negative glitch (in) and eliminate it from the waveform of the output (Out) of the SR latch 218.

In general and according to the forgoing, a deglitch circuit (or a deglitcher) in one embodiment of the present invention can be used in a system where the desired signal is known to maintain high or low levels for minimum periods of time. For example, the input signal may come from a separate IC, and it may be specified to have a minimum pulse width of about 100 ns. In this case, any signals which are presented to the circuit which are less than 100 ns in width can be assumed to be noise (i.e. they are undesired signals) . A pulse of, say, 5 ns, could then be safely ignored, since it would not be expected to have come from the IC which produced the signal.

In some cases, improperly designed digital circuits can produce glitches. Hence, in these cases, short pulses would actually come from the input signal source, but those signals would still be undesirable, and hence considered noise. Thus, the embodiment of the present invention has further utility in that it can be used to filter glitches which may be generated by such circuits.

In another example, a push-button switch may generate the input signal. As the switch is typically actuated by a human user, the switch will be closed or open for some minimum amount of time, since humans cannot push and release the switch very rapidly. Thus, in one embodiment of the present invention, any switch closures less than about 3 ms to 10 ms are assumed to be unintended, with the exact time being dependent upon the mechanical properties of the switch.

Glitches may also be handled by employing algorithms in firmware which take multiple samples of the input signal, and then analyze a set of samples to recognize and then filter glitches. As discussed above, the drawback to a firmware (or a firmware only) approach is that the firmware must be running when glitches occur in order to process them. Since multiple samples are needed, the firmware must run faster in order to process the data gathered. By contrast, a deglitcher in an embodiment of the present invention removes the noise from the signal before any firmware processes it. So, the firmware is then able to run slower since it does not need to take as many samples, and in most cases only needs to take one sample of the input signal.

In battery-powered systems, large portions of the system may be shut down when there is no significant input detected. Without a deglitcher, any noise on input signals may be incorrectly interpreted as an intended input signal causing the logic to be powered up so that the input signal has to be processed further to determine if it is noise or an intended (or valid) input signal. With a deglitcher, these “false alarms” may be reduced or even eliminated, which allows the system to remain in a low-power state more often, and in turn lengthens the battery life of the system.

In summary, an embodiment of the invention described herein teaches improved systems and methods for identifying and removing both positive and negative glitches from a signal using a digital logic solution. While certain exemplary embodiments have been described in detail and shown in the accompanying drawings, it is to be understood that such embodiments are merely illustrative of and not restrictive of the broad invention. It will thus be recognized that various modifications may be made to the illustrated and other embodiments of the invention described above, without departing from the broad inventive scope thereof. For example, ASIC, switch type signal producing nodes, and/or remote sensor type signal producing nodes have been illustrated, but it should be apparent that the inventive concepts described above would be equally applicable to other types of signal producing nodes and/or circuits. In view of the above it will be understood that the invention is not limited to the particular embodiments or arrangements disclosed, but is rather intended to cover any changes, adaptations or modifications which are within the scope and spirit of the invention as defined by the appended claims.

What is claimed is:

1. A deglitch circuit coupled between a signal producing node and a signal processing node, the deglitch circuit comprising:
a delay block coupled to receive a data signal from the signal producing node and to produce a delay data signal;
a first logic gate having a first gate input, a second gate input, and a first gate output, the first gate input being coupled to receive the data signal from the signal producing node and the second gate input being coupled to receive the delay data signal from the delay block;
a second logic gate having a third gate input, a fourth gate input, and a second gate output, the third gate input being coupled to receive the data signal from the signal producing node and the fourth gate input being coupled to receive the delay data signal from the delay block; and
an SR latch having a first latch input, a second latch input, and a latch output, the first latch input being coupled to the first gate output and the second latch input being coupled to the second gate output;
wherein the SR latch provides a deglitched data signal based on the data signal via the latch output to the signal processing node for processing.

2. The deglitch circuit of claim 1, wherein the first logic gate removes a positive glitch from the data signal and wherein the second logic gate removes a negative glitch from the data signal.

3. The deglitch circuit of claim 1, wherein the delay block, the first gate input, and the third gate input are coupled to receive the data signal from the signal producing node in a substantial parallel manner.

4. The deglitch circuit of claim 1, wherein the second gate input and the fourth gate input are coupled to receive the delay data signal from the delay block in a substantial parallel manner.

5. The deglitch circuit of claim 1, wherein the delay block, the first gate input, and the third gate input are coupled to receive the data signal from the signal producing node in a substantial parallel manner and wherein the second gate input and the fourth gate input are coupled to receive the delay data signal from the delay block in a substantial parallel manner.

6. The deglitch circuit of claim 5, wherein the delay block, the first gate input, and the third gate input are coupled to receive the data signal from the signal producing node via a conductive medium comprising a plurality of conductive traces.

7. The deglitch circuit of claim 1, wherein the first logic gate comprises an and-gate and wherein the second logic gate comprises a nor-gate.

8. The deglitch circuit of claim 7, wherein the delay block, the first gate input, and the third gate input are coupled to receive the data signal from the signal producing node in a substantial parallel manner.

9. The deglitch circuit of claim 7, wherein the second gate input and the fourth gate input are coupled to receive the delay data signal from the delay block in a substantial parallel manner.

10. The deglitch circuit of claim 7, wherein the delay block, the first gate input, and the third gate input are coupled to receive the data signal from the signal producing node in a substantial parallel manner and wherein the second gate input and the fourth gate input are coupled to receive the delay data signal from the delay block in a substantial parallel manner.

11. The deglitch circuit of claim 7, wherein the delay block, the first gate input, and the third gate input are coupled to receive the data signal from the signal producing node via a conductive medium comprising one of a conductive trace and a wire.

12. The deglitch circuit of claim 11, wherein the delay block, the and-gate, the nor-gate, and the SR-latch are parts of an application specific integrated circuits (ASIC) chip.

13. The deglitch circuit of claim 11, wherein the data signal is provided from the signal producing node through the delay block, the and-gate, the nor-gate, and the SR-latch to the signal processor using hardwire means.

14. The deglitch circuit of claim 1, wherein the delay block, the first gate input, and the third gate input are coupled to receive the data signal from the signal producing node via a plurality of conductive traces and wherein the delay block, the first logic gate, the second logic gate, and the SR-latch are parts of an application specific integrated circuits (ASIC) chip.

15. The deglitch circuit of claim 14, wherein the data signal is provided from the signal producing node through the ASIC chip to the signal processor using hardwire means.

16. A method of deglitching a data signal using a digital logic circuit, the method comprising:
receiving a data signal;
delaying the data signal for a predetermined period to produce a delay data signal from the received data signal;
providing in a substantially parallel manner the data signal to a first gate input of a first logic gate and a first gate input of a second logic gate;
providing in a substantially parallel manner the delay data signal to a second gate input of the first logic gate and the second gate input of the second logic gate;
coupling an SR latch to an output of the first logic gate and an output of the second logic gate; and
providing a deglitched data signal based on the data signal from the SR latch.

17. The method of claim 16, wherein the first logic gate removes a positive glitch from the data signal and wherein the second logic gate removes a negative glitch from the data signal.

18. The method of claim 16, wherein the receiving the data signal comprises receiving the data signal from a signal producing node via a plurality of conductive traces.

19. The method of claim 16, wherein the first logic gate comprises an and-gate and wherein the second logic gate comprises a nor-gate.

20. The method of claim 16, wherein the delaying the data signal for the predetermined period comprises:
deciding a size of a glitch to be removed;
providing a decided size large enough so that an SR latch timing constraint of the SR latch is met; and
setting a delay block to the decided size.

21. A deglitch circuit coupled between a signal producing node and a signal processing node, the deglitch circuit comprising:
first means for receiving a data signal;
second means for delaying the data signal for a predetermined period to produce a delay data signal from the data signal;
third means for receiving the data signal and the delay data signal and for logically removing a positive glitch from the data signal;
fourth means for receiving the data signal and the delay data signal and for logically removing a negative glitch from the data signal; and
fifth means for logically producing a deglitched data signal from the data signal, the fifth being coupled to the third means and the fourth means.

22. The deglitch circuit of claim 21, wherein the third means comprises an and-gate, wherein the fourth means comprises a nor-gate, and wherein the fifth means comprises an SR latch.

23. The deglitch circuit of claim 21, wherein the second means comprises a delay block for setting a glitch size.
